(19) United States
(12) Patent Application Publication
(10) Pub. No.: US 2012/0211828 A1
(43) Pub. Date: Aug. 23, 2012

(54) HYBRID SPLIT GATE SEMICONDUCTOR

(75) Inventors: Madhur Bobde, Sunnyvale, CA (US); Qufei Chen, San Jose, CA (US); Misbah Ul Azam, Fremont, CA (US); Kyle Terrill, Santa Clara, CA (US); Yang Gao, San Jose, CA (US); Sharon Shi, San Jose, CA (US)

(73) Assignee: VISHAY-SILICONIX, Santa Clara, CA (US)

(21) Appl. No.: 13/460,567

(22) Filed: Apr. 30, 2012

Related U.S. Application Data
(63) Continuation-in-part of application No. 12/603,028, filed on Oct. 21, 2009.
Application No. 12/603,028 is a continuation-in-part of application No. 12/869,554, filed on Aug. 26, 2010.

(51) Int. Cl. H01L 29/78

(52) U.S. Cl. 257/330; 257/E29.262

(57) ABSTRACT

In an embodiment in accordance with the present invention, a semiconductor device includes a vertical channel region, a gate at a first depth on a first side of the vertical channel region, a shield electrode at a second depth on the first side of the vertical channel region, and a hybrid gate at the first depth on a second side of the vertical channel region. The region below the hybrid gate on the second side of the vertical channel region is free of any electrodes.

### RELATED CASES

This application is a Continuation in Part of, and claims priority to co-pending, commonly-owned U.S. patent application Ser. No. 12/603,028, entitled, “Split Gate Semiconductor Device with Curved Gate Oxide Profile,” filed Oct. 21, 2009 to Gao et al. This application is a Continuation in Part of, and claims priority to co-pending, commonly-owned U.S. patent application Ser. No. 12/869,554, entitled, “Structures and Methods of Fabricating Split Gate MIS Devices,” filed Aug. 26, 2010, to Terrill et al. All such applications are incorporated herein by reference in their entireties.

### FIELD OF INVENTION

Embodiments of the present invention relate to the field of integrated circuit design and manufacture. More specifically, embodiments of the present invention relate to systems and methods for a hybrid split gate semiconductor.

### BACKGROUND

Split-gate power MOSFETs (metal-oxide-semiconductor field-effect transistors) have recognized advantages in comparison to power MOSFETs with non-split gate structures. However, conventional split-gate power MOSFETs do not substantially benefit from decreases in process geometry, e.g., a decrease in the pitch between gates. Sub-micron cell pitch scaling is generally desirable for increasing the channel density, which in turn decreases the channel resistance per unit area. However, such scaling may also result in an undesirable narrower mesa width per unit area, which may increase the drift region resistance. In addition, a higher density of gates and shield electrodes may result in a deleterious higher gate charge and output capacitance.

### SUMMARY OF THE INVENTION

Therefore, what is needed are systems and methods for hybrid split gate semiconductor devices. What is additionally needed are systems and methods for hybrid split gate semiconductor devices with improved performance at finer, e.g., smaller, inter-gate pitch dimensions. A further need exists for systems and methods for hybrid split gate semiconductor devices that are compatible and complementary with existing systems and methods of integrated circuit design, manufacturing and test. Embodiments of the present invention provide these advantages.

In an embodiment in accordance with the present invention, a semiconductor device includes a vertical channel region, a gate at a first depth on a first side of the vertical channel region, a shield structure at a second depth on the first side of the vertical channel region, and a hybrid gate at the first depth on a second side of the vertical channel region. The region below the hybrid gate on the second side of the vertical channel region is free of any gate or electrode.

In accordance with another embodiment of the present invention, a structure includes a first elongated structure disposed beneath a surface of a semiconductor substrate. The first elongated structure includes a gate structure at a first depth below the surface and a shield structure at a second depth below the surface. The structure further includes a second elongated structure formed beneath the surface comprising a hybrid gate structure at the first depth. The second elongated structure is free of another gate or electrode structure. The first and second elongated structures may be parallel.

In accordance with yet another embodiment of the present invention, a structure includes a first plurality of first trenches formed in a semiconductor substrate to a first depth and a second plurality of second trenches formed in the semiconductor substrate to a second depth. The first trenches are parallel with the second trenches and the first trenches alternate with the second trenches. The first trenches may be filled with first materials comprising a first polysilicon and a second polysilicon, above the first polysilicon.

In accordance with a method embodiment of the present invention, a plurality of first trenches is formed in a semiconductor substrate to a first depth. A plurality of second trenches is formed in the semiconductor substrate to a second depth. The first plurality of trenches are parallel with the second plurality of trenches. The trenches of the plurality of first trenches alternate with and are adjacent to trenches of the plurality of second trenches.

In accordance with another method embodiment of the present invention, a plurality of trenches are formed in a semiconductor substrate to a first depth. The trenches of the plurality of trenches are parallel to one another. Alternate trenches of the plurality of trenches are masked and the depth of unmasked trenches of the plurality of trenches is increased to a second depth. A patterned layer of pad oxide may form a mask for the increasing.

In accordance with still another method embodiment of the present invention, a vertical trench metal oxide semiconductor field effect transistor (MOSFET) device comprising a plurality of parallel filled-trench structures is formed. The parallel filled-trench structures are spaced at a pitch distance of 0.6 microns or less, and each of the parallel filled-trench structures include a gate structure of the MOSFET.

### BRIEF DESCRIPTION OF THE DRAWINGS

The accompanying drawings, which are incorporated in and form a part of this specification, illustrate embodiments of the invention and, together with the description, serve to explain the principles of the invention. Unless otherwise noted, the drawings are not drawn to scale.

FIG. 1 illustrates cross sectional view of a trench portion of a hybrid split gate semiconductor device, in accordance with embodiments of the present invention.

FIGS. 2A, 2B, 2C, 2D, 2E and 2F illustrate diagrams according to a method of manufacturing a hybrid split gate semiconductor, in accordance with embodiments of the present invention.

### DETAILED DESCRIPTION

Reference will now be made in detail to various embodiments of the invention, Hybrid Split Gate Semiconductor, examples of which are illustrated in the accompanying drawings. While the invention will be described in conjunction with these embodiments, it is understood that they are not intended to limit the invention to these embodiments. On the contrary, the invention is intended to cover alternatives, modifications and equivalents, which may be included within the spirit and scope of the invention as defined by the appended claims. Furthermore, in the following detailed description of the invention, numerous specific details are set forth in order to provide a thorough understanding of the invention. However, it will be recognized by one of ordinary skill in the art that the invention may be practiced without these specific details. In other instances, well known methods, procedures, components, and circuits have not been described in detail as not to unnecessarily obscure aspects of the invention.

### Notation and Nomenclature

Some portions of the detailed descriptions which follow are presented in terms of procedures, steps, logic blocks, processing, operations and other symbolic representations of operations on data bits that may be performed on computer memory. These descriptions and representations are the means used by those skilled in the data processing arts to most effectively convey the substance of their work to others skilled in the art. A procedure, computer executed step, logic block, process, operation, etc., is here, and generally, conceived to be a self-consistent sequence of steps or instructions leading to a desired result. The steps are those requiring physical manipulations of physical quantities. Usually, though not necessarily, these quantities take the form of electrical or magnetic signals capable of being stored, transferred, combined, compared, and otherwise manipulated in a computer system. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the following discussions, it is appreciated that throughout the present invention, discussions utilizing terms such as “attaching” or “processing” or “singulating” or “forming” or “doping” or “filling” or “etching” or “roughening” or “accessing” or “performing” or “generating” or “adjusting” or “creating” or “executing” or “continuing” or “indexing” or “processing” or “computing” or “translating” or “calculating” or “determining” or “measuring” or “gathering” or “running” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

The figures are not drawn to scale, and only portions of the structures, as well as the various layers that form those structures, may be shown in the figures. Furthermore, fabrication processes and operations may be performed along with the processes and operations discussed herein; that is, there may be a number of process operations before, in between and/or after the operations shown and described herein. Importantly, embodiments in accordance with the present invention can be implemented in conjunction with these other (perhaps conventional) processes and operations without significantly perturbing them. Generally speaking, embodiments in accordance with the present invention may replace and/or supplement portions of a conventional process without significantly affecting peripheral processes and operations.

As used herein, the letter “n” refers to an n-type dopant and the letter “p” refers to a p-type dopant. A plus sign “+” or a minus sign “−” is used to represent, respectively, a relatively high or relatively low concentration of the dopant.

The term “channel” is used herein in the accepted manner. That is, current moves within a FET in a channel, from the source connection to the drain connection. A channel can be made of either n-type or p-type semiconductor material; accordingly, a FET is specified as either an re-channel or p-channel device. Some of the figures are discussed in the context of an n-channel device, specifically an n-channel power MOSFET; however, embodiments according to the present invention are not so limited. That is, the features described herein can be utilized in a p-channel device. The discussion of an n-channel device can be readily mapped to a p-channel device by substituting p-type dopant and materials for corresponding n-type dopant and materials, and vice versa.

The term “trench” has acquired two different, but related meanings within the semiconductor arts. Generally, when referring to a process, e.g., etching, the term trench is used to mean or refer to a void of material, e.g., a hole or ditch. Generally, the length of such a hole is much greater than its width or depth. However, when referring to a semiconductor structure or device, the term trench is used to mean or refer to a solid vertical structure, disposed beneath a surface of a substrate, having a complex composition, different from that of the substrate, and adjacent to a channel of a field effect transistor (FET). The structure comprises, for example, a gate of the FET. Accordingly, a trench semiconductor device generally comprises a mesa structure, which is not a trench, and portions, e.g., one half, of two adjacent structural “trenches.”

It is to be appreciated that although the semiconductor structure commonly referred to as a “trench” may be formed by etching a trench and then filling the trench, the use of the structural term herein in regards to embodiments of the present invention does not imply, and is not limited to such processes.

### Hybrid Split Gate Semiconductor

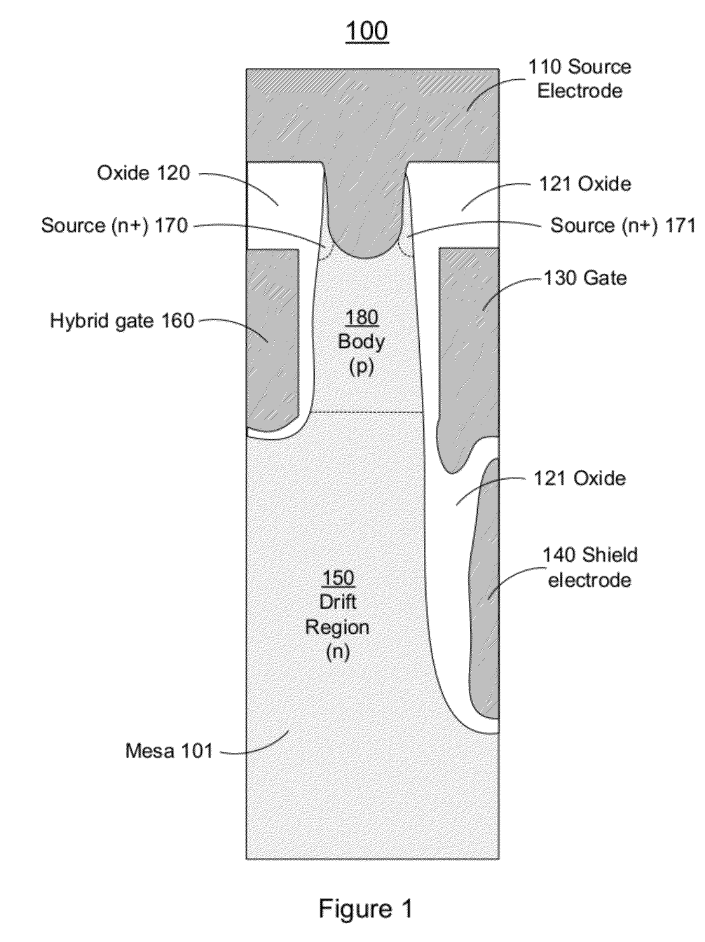

FIG. 1 illustrates cross sectional view of a trench portion of a hybrid split gate semiconductor device 100, in accordance with embodiments of the present invention. Hybrid split gate semiconductor device 100 comprises a source electrode 110 in contact with a mesa 101 of semiconductor material, e.g., Silicon. Mesa 101 is doped to form regions of a vertical trench metal-oxide-semiconductor field-effect transistor, e.g., source regions 170 and 171, body region 180 and drift region 150. Exemplary conductivity types are illustrated, e.g., source regions 170 and 171 may be n+, body region 180 may be p, and drift region 150 may be n or n+. Mesa 101 may comprise epitaxially-formed material, in some embodiments. Hybrid split gate semiconductor device 100 further comprises a drain region (not shown), typically at the bottom of a substrate, e.g., below mesa 101 in FIG. 1.

Hybrid split gate semiconductor device 100 also comprises a gate 130 and a shield electrode 140, forming a split gate. Gate 130 is electrically coupled to a gate electrode (not shown). Shield electrode 140 is electrically coupled to source electrode 110. Oxide 121, e.g., a gate oxide, separates gate 130 and shield electrode 140.

In accordance with embodiments of the present invention, hybrid split gate semiconductor device 100 further comprises hybrid gate 160. Hybrid gate 160 is electrically coupled to gate 130. Oxide 120, e.g., a gate oxide, separates hybrid gate 160 from mesa 101.

It is to be appreciated that many trench power semiconductors comprise multiple rows of trenches, and that the gates of many trenches are often coupled together. Embodiments in accordance with the present invention are well-suited to such arrangements.

In accordance with embodiments of the present invention, hybrid split gate semiconductor device 100 comprises one gate on one side of a mesa, e.g., hybrid gate 160 on the left of mesa 101, as illustrated in FIG. 1, and a split gate structure on the other side of a mesa, e.g., gate 130 and shield electrode 140 on the on the right of mesa 101, as illustrated in FIG. 1.

It is to be appreciated that a conventional split-gate device comprises a split gate, e.g., comprising a gate and a shield electrode, on both sides of the substrate mesa. In accordance with embodiments of the present invention, hybrid split gate semiconductor device 100 lacks a split gate structure on both sides of a mesa, in contrast to a conventional split-gate device. Rather, hybrid split gate semiconductor device 100 lacks a second, or shield electrode, on one side of the mesa, for example the left side of mesa 101 as illustrated in FIG. 1.

In accordance with the conventional art, a process shrink, or a decrease in trench pitch, may frequently be of no benefit, or may even be detrimental to the performance of split-gate trench MOSFETs (metal-oxide-semiconductor field-effect transistors). For example, a decreased trench pitch may enable a greater channel width in a given die area, advantageously decreasing channel resistance. However, such decreased trench pitch may also deleteriously increase output capacitance, for example due to increased density of shield electrodes.

In accordance with embodiments of the present invention, shield electrode pitch is half of overall gate pitch. For example, there are two gates, e.g., gate 130 and hybrid gate 160, for every shield electrode, e.g., shield electrode 140. In this novel manner, channel resistance may be decreased by decreasing trench pitch while limiting the increase in output capacitance. For example, because each device only has one shield electrode, channel resistance decreases faster than gate capacitance increases, resulting in overall improvement in such devices, in comparison to the conventional art. Another advantage of eliminating every alternate shield electrode is the availability of a wider mesa for current conduction. Such a wider mesa may lower the total resistance of the power MOSFET.

Power MOSFETs are frequently characterized by their “Figure of Merit.” Figure of Merit refers to the product of a device's channel resistance multiplied by the gate charge. In general, devices with a lower Figure of Merit are more desirable.

Table 1, below, illustrates results that demonstrate some advantages of the present invention.

TABLE 1

| | | | High Density |
|---|---|---|---|
| | Low Density | High Density | Hybrid |
| Parameter | Split Gate | Split Gate | Split Gate |
| Resistance (mOhm · mm2) | 5.21 | 5.25 | 4.24 |
| Gate Charge (nC/mm2) | 6.77 | 8.70 | 9.16 |
| Figure of Merit | 35.27 | 45.68 | 38.84 |
| Output Charge (nC/mm2) | 11.8 | 12 | 7.44 |

The columns of Table 1 correspond to three exemplary test versions of vertical trench MOSFETs. The column labeled “Low Density Split Gate” refers to a device with a conventional split gate arrangement, at a pitch of 0.8 μm, designed for a nominal 25 volt operation. The column labeled “High Density Split Gate” refers to a device with a conventional split gate, at a pitch of 0.6 μm, designed for a nominal 25 volt operation. Notably, the “High Density Split Gate” device is constructed with a tighter, e.g., closer, pitch, 0.6 μm, in comparison to a 0.8 μm pitch for the “Low Density Split Gate” device. The column labeled “High Density Hybrid Split Gate” refers to a device with a novel hybrid gate arrangement, designed for a nominal 25 volt operation, at a pitch of 0.6 μm, in accordance with embodiments of the present invention.

The term “Resistance” in Table 1 refers to the MOSFET “ON” resistance for a device with active area of 1 mm², for a gate bias of 4.5 volts. The term “Gate Charge” in Table 1 refers to the gate charge require to drive the gate terminal to 4.5 volts, for turning the gate on for a device with 1 mm² active area.

The term “Output Charge” in Table 1 refers to the charge associated with charging/discharging the drain to source output capacitance when the MOSFET is switched from ON state to OFF state, measured in nano Coulombs for a 1 mm² active area.

The term “Figure of Merit in Table 1 refers to the product of a device's channel resistance multiplied by the gate charge, and is an indicator of its conduction losses & switching losses combined. For example, for the “Low Density Split Gate” device, the Figure of Merit is:

RDS2A*QG4.5=5.21*6.77=35.27.

In general, devices with a lower Figure of Merit are more desirable.

It is to be appreciated that the “High Density Split Gate” device is generally less desirable than the larger “Low Density Split Gate” device. For example, while many of the parameters are similar among the two devices, Gate Charge and Output Charge are substantially different. As a result, the smaller pitch “High Density Split Gate” device has a larger, or less desirable, Figure of Merit.

In contrast, in accordance with embodiments of the present invention, the “High Density Hybrid Split Gate” device shows improved resistance, in comparison to both the “Low Density Split Gate” and “High Density Split Gate” devices. It is to be appreciated that the Resistance improvement is significant, e.g., about 20 percent in comparison to the conventional “Low Density Split Gate” device.

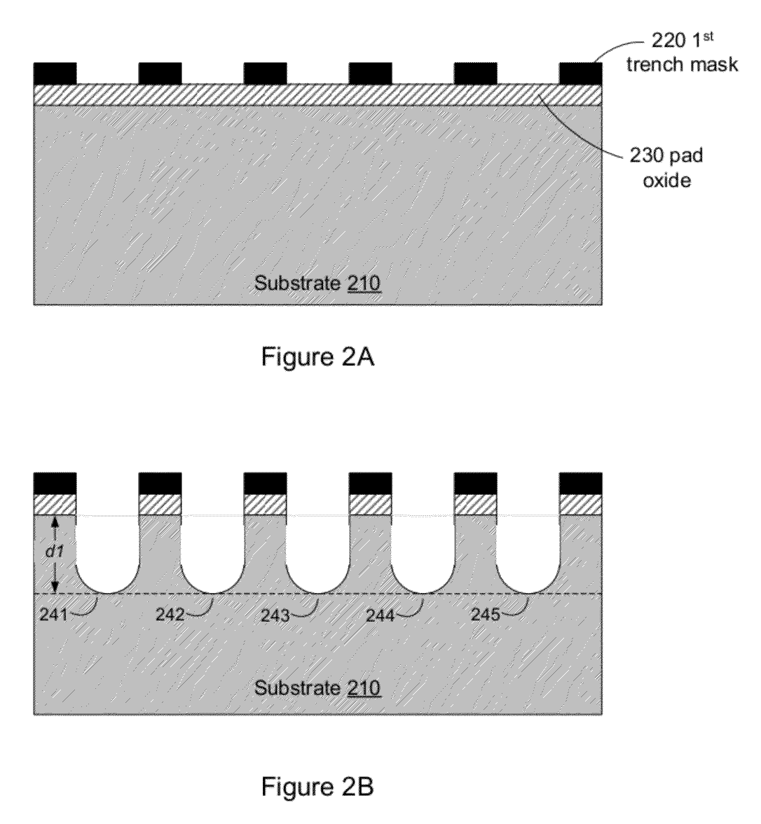

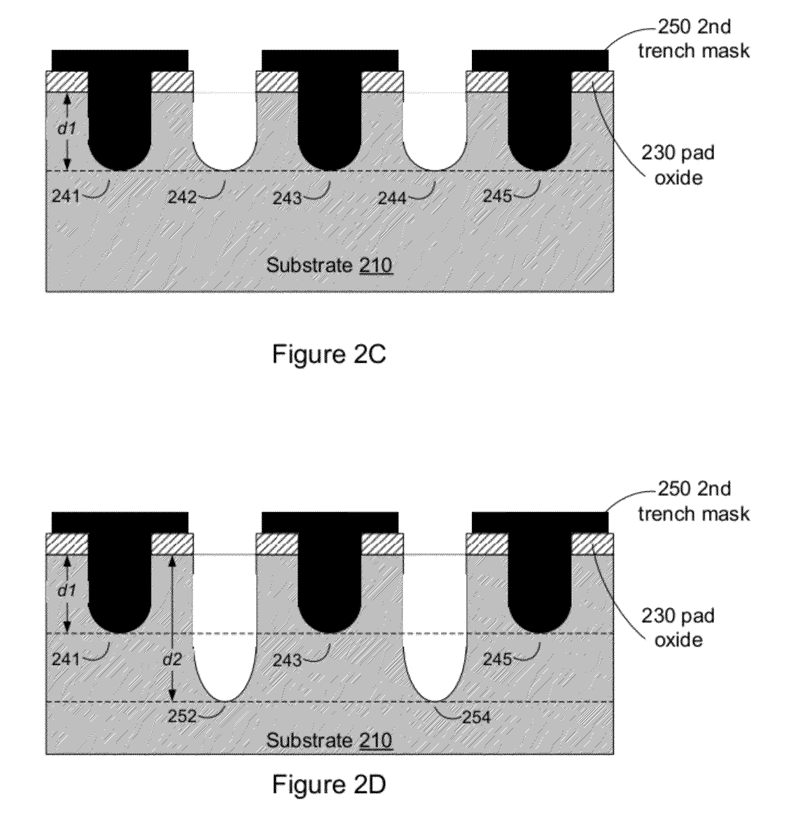

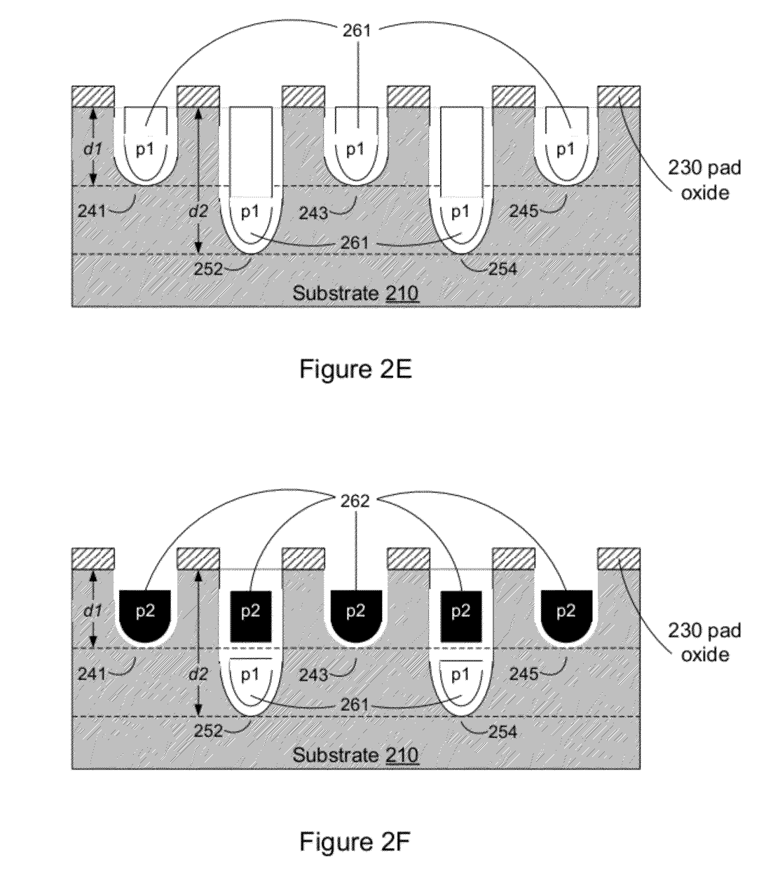

FIGS. 2A-2F illustrate a method of manufacturing a hybrid split gate semiconductor, in accordance with embodiments of the present invention. In accordance with embodiments of the present invention, FIG. 2A illustrates a first trench mask 220 applied to a pad oxide 230, which is applied to a substrate 210. Substrate 210 may comprise bulk material and/or one or more epitaxial layers.

In accordance with embodiments of the present invention, FIG. 2B illustrates a plurality of trenches, 241-245, formed through pad oxide 230 and into substrate 210, for example, via a reactive ion etch (RIE) process, based on first trench mask 220. It is appreciated that the formation of trenches 241-245 may comprise separate operations to etch oxide 230 and to etch the substrate 210. Substrate 210 may comprise epitaxially grown materials, in some embodiments. It is appreciated that embodiments in accordance with the present invention are well suited to any suitable method of forming trenches. Trenches 241-245 are formed to a depth d1 below a surface of substrate 210.

In accordance with embodiments of the present invention, FIG. 2C illustrates a second trench mask 250 applied over alternate trenches, e.g., trenches 241, 243 and 245. The second trench mask 250 may optionally fill the covered trenches, e.g., trenches 241, 243 and 245. It is appreciated that trenches 242 and 244 are not covered by trench mask 250 and remain exposed.

In accordance with embodiments of the present invention, FIG. 2D illustrates etching of trenches 242 and 244 to a deeper depth d2 below a surface of substrate 210, forming deep trenches 252 and 254. Trenches 252 and 254 are etched, for example, via a reactive ion etch (RIE) process, based on second trench mask 250 and the pattern of pad oxide 230. It is appreciated that embodiments in accordance with the present invention are well suited to any suitable method of forming such trenches.

In accordance with embodiments of the present invention, the alignment of trench mask 250 with the edges of the uncovered trenches 242, 244, is not necessarily critical, as the pad oxide 230, through which the trenches 242 and 244 were etched, may form a self-aligned mask for etching of trenches 253 and 254. For example, the formation of trenches 241-245 etched both oxide 230 and the substrate 210. Etching trenches 242 and 244 to a deeper depth does not require etching of oxide 230, and hence oxide 230 may form a mask for etching trenches 252 and 254.

In accordance with embodiments of the present invention, FIG. 2E illustrates deposition of first polysilicon 261 trenches 241, 243, 245 and deep trenches 252 and 254. As will be described further below, first polysilicon 261 will form split or shield electrodes of a hybrid split gate semiconductor device. The poly p1 will be etched off from all trenches to about depth d1 during an etch back (recess etch) process. It is appreciated that such recess etching will remove all poly p1 261 from trenches 241, 243 and 245, leaving poly p1 261 only in the bottom of deep trenches 252 and 254.

In accordance with embodiments of the present invention, FIG. 2F illustrates deposition of second polysilicon 262 in all trenches 241, 252, 243, 254, and 245. Prior to filling with of second polysilicon 262, an oxide may be formed, at least in deep trenches 252 and 254, to separate first polysilicon p1 161 from second polysilicon p2 262. As will be described further below, second polysilicon 262 will form standard gates, e.g., the top gate or “non-shield” electrode of a split-gate semiconductor, and hybrid gates of a hybrid split gate semiconductor device.

U.S. patent application Ser. No. 12/603,028, entitled, “Split Gate Semiconductor Device with Curved Gate Oxide Profile,” filed Oct. 21, 2009 to Gao et al. and U.S. patent application Ser. No. 12/869,554, entitled, “Structures and Methods of Fabricating Split Gate MIS Devices,” filed Aug. 26, 2010, to Terrill et al., incorporated herein by reference in their entireties, illustrate additional details of formation of split-gate semiconductor devices. Embodiments in accordance with the present invention are compatible with the processes and materials described in these referenced applications.

With reference to FIG. 1 and FIG. 2F, p2 polysilicon 262 in trench 254 forms a gate, e.g., gate 130. P1 polysilicon 261 in trench 254 forms a shield electrode, e.g., shield electrode 140. P2 polysilicon 262 in trench 243 forms a hybrid gate, e.g., hybrid gate 160. A portion of substrate 210, which may include bulk and/or epitaxial material, between trenches 254 and 243 forms a mesa, e.g., mesa 101.

It is to be appreciated that the structures in and of deep trench 254 and the structures in and of trench 245, also form a hybrid split gate semiconductor device. In this arrangement, the split gate is on the left, e.g., comprising a shield electrode formed by p1 polysilicon 261 in deep trench 254, and a gate formed by p2 polysilicon 262 in deep trench 254. The hybrid gate is on the right, e.g., formed by p2 polysilicon 262 in trench 245. For example, the hybrid split gate semiconductor device formed by the structures in and of trench 245 and deep trench 254 may be seen as a mirror image of the hybrid split gate semiconductor device 100, as illustrated in FIG. 1.

It is to be appreciated that the regions between the trenches may be doped to form regions of a vertical trench metal-oxide-semiconductor field-effect transistor, e.g., source regions 170 and 171, body region 180 and drift region 150, as illustrated in FIG. 1. Such doping may be performed prior to, or after, formation of the trenches, and may also take place at different stages of processing. For example, body region 180 and drift region 150 may be doped prior to formation of any trenches, while source regions 170 and 171 may be doped after formation and filling of the trenches. Embodiments in accordance with the present invention are well suited to any sequence and/or processes for doping the various regions of a hybrid split gate semiconductor device.

Embodiments in accordance with the present invention provide systems and methods for hybrid split gate semiconductor devices. In addition, embodiments in accordance with the present invention provide systems and methods for hybrid split gate semiconductor devices with improved performance at finer inter-gate pitch dimensions. Further, embodiments in accordance with the present invention provide systems and methods for hybrid split gate semiconductor devices that are compatible and complementary with existing systems and methods of integrated circuit design, manufacturing and test.

Various embodiments of the invention are thus described. While the present invention has been described in particular embodiments, it should be appreciated that the invention should not be construed as limited by such embodiments, but rather construed according to the below claims.

What is claimed is:

1. A semiconductor device comprising:
a vertical channel region;
a gate at a first depth on a first side of said vertical channel region;
a shield electrode at a second depth on said first side of said vertical channel region; and
a hybrid gate at said first depth on a second side of said vertical channel region,
wherein the region below said hybrid gate on said second side of said vertical channel region is free of any electrode.

2. The semiconductor device of claim 1 wherein said gate, said shield electrode and said hybrid gate comprise polysilicon.

3. The semiconductor device of claim 1 wherein said gate and said hybrid gate are electrically coupled.

4. The semiconductor device of claim 1 wherein said gate and said shield electrode are physically separated by an oxide.

5. The semiconductor device of claim 1 wherein said and said hybrid gate are physically separated by said vertical channel region.

6. The semiconductor device of claim 1 further comprising a source electrode coupled to said shield electrode.

7. The semiconductor device of claim 1 comprising a trench metal oxide semiconductor field effect transistor (MOSFET) device.

8. A structure comprising:
a first elongated structure disposed beneath a surface of a semiconductor substrate comprising:
a gate structure at a first depth below said surface;
a shield electrode structure at a second depth below said surface; and
a second elongated structure formed beneath said surface comprising a hybrid gate structure at said first depth,
wherein said second elongated structure is free of another electrode.

9. The structure of claim 8 wherein said first and second elongated structures are parallel.

10. The structure of claim 8 wherein said gate structure and said hybrid gate structure are electrically coupled.

11. The structure of claim 8 wherein said gate structure and said shield electrode structure are physically separated by an oxide.

12. The structure of claim 8 wherein said semiconductor substrate is doped to form a body region between said first and second elongated structures.

13. The structure of claim 8 wherein said semiconductor substrate further comprises source regions and a drift region.

14. The structure of claim 8 comprising a trench power metal oxide semiconductor field effect transistor (MOSFET) device.

15. A structure comprising:
a first plurality of first trenches formed in a semiconductor substrate to a first depth; and
a second plurality of second trenches formed in said semiconductor substrate to a second depth,
wherein said first trenches are parallel with said second trenches, and
wherein further said first trenches alternate with said second trenches.

16. The structure of claim 15 wherein said first trenches are filled with first materials comprising a first polysilicon and a second polysilicon, above said first polysilicon.

17. The structure of claim 16 wherein said second trenches are filled with second materials comprising said second polysilicon.

18. The structure of claim 16 wherein said first materials comprise an oxide separating said first polysilicon from said second polysilicon.

19. The structure of claim 15 wherein said semiconductor substrate is doped to form a third plurality of body regions between said first and second trenches.

20. The structure of claim 15 comprising a trench power metal oxide semiconductor field effect transistor (MOSFET) device.
